(19) United States
(12) Patent Application Publication
(10) Pub. No.: US 2016/0307636 A1
(43) Pub. Date: Oct. 20, 2016

(54) METHOD AND APPARATUS FOR IMPROVING DATA RETENTION AND READ-PERFORMANCE OF A NON-VOLATILE MEMORY DEVICE

(71) Applicant: MACRONIX INTERNATIONAL CO., LTD., Hsinchu (TW)

(72) Inventors: Ya Jui Lee, Taichung City (TW); Kuan Fu Chen, Taipei City (TW)

(21) Appl. No.: 14/689,489

(22) Filed: Apr. 17, 2015

(51) Int. Cl. G11C 16/34; G11C 16/12

(52) U.S. Cl. CPC G11C 16/3427; G11C 16/12

(57) ABSTRACT

Methods and apparatuses are contemplated herein for enhancing the read performance and data retention of nonvolatile memory devices. In an example embodiment, a method is provided for controlling a nonvolatile memory device that includes a matrix of memory cells, wherein each memory cell in the matrix includes a programmable floating gate. The method includes programming a floating gate of a first memory cell of the nonvolatile memory device, and shifting a voltage of the floating gate of the first memory cell of the nonvolatile memory device by creating a coupling effect that impacts the floating gate of the first memory cell. In this regard, the method may include programming one or more nearby memory cells, in which case the coupling effect may comprise a floating gate coupling effect between the first memory cell and the one or more nearby memory cells.

### TECHNOLOGICAL FIELD

Example embodiments of the present invention relate generally to non-volatile memory devices and, more particularly, to improving the data retention and read performance of non-volatile memory devices.

### BACKGROUND

Semiconductor devices are typically classified as either volatile semiconductor devices, which require power to maintain storage of data, or non-volatile semiconductor devices, which can retain data even upon removal of a power source. An example non-volatile semiconductor device is a flash memory device, which generally includes a matrix of memory cells arranged in rows and columns. Each memory cell in the matrix includes a transistor structure having a gate, a drain, a source, and a channel defined between the drain and the source. Each memory cell is located at an intersection between a word line and a bit line, wherein the gate is connected to the word line, the drain is connected to the bit line, and the source is connected to a source line, which in turn is connected to common ground. The gate of a conventional flash memory cell generally comprises a dual-gate structure, including a control gate and a floating gate, wherein the floating gate is suspended between two oxide layers to trap electrons that program the cell.

Flash memory devices may in turn be classified as NOR or NAND flash memory devices. Of these, NAND flash memory typically offers faster program and erase speeds, in large part due to its serialized structure, whereby program and erase operations may be performed on entire strings of memory cells.

However, given that the usage of NAND flash memory has increased significantly, there are some markets in which high performance read operations and data retention are becoming more important than program performance. For instance, high read cycles and good data retention are required for game cards, and automotive GPS systems, among other markets. Thus, there is a growing need for NAND flash memory devices that demonstrate greater data retention and read performance.

NAND flash memory devices program memory cells using Fowler-Nordheim tunneling, which can produce traps in the oxide layers surrounding a floating gate. When electrons fill these traps, the potential barrier of the oxide layers increases. While future program operations will continue to apply the same charge to the memory cell as past program operations, the increased potential barrier of the oxide layers reduces the charge added to the floating gate during a program operation, and thus results in a lower threshold voltage of the floating gate.

Some attempts to improve data retention and performance have focused on avoiding disturbances to memory cells. Specifically, flash memory devices are susceptible to memory corruption over time as a result of repeated program and read operations, which can cause “disturbs” to memory cells that are not the subject of the program or read operations. For instance, when performing a read operation of a memory cell in a selected word line, a read voltage is applied to the selected word line while a pass voltage (VpassR) is applied to the unselected word lines. The pass voltage applied to the unselected word lines must be sufficiently high that it renders the memory cells of the unselected word line conductive regardless of whether those memory cells are programmed or not. Repeated applications of this pass voltage can cause the floating gate of a memory cell in an unselected word line having a “1” (or unprogrammed) state to inadvertently acquire a weak charge that will erroneously suggest that the memory cell has a “0” (or programmed) state.

Thus, to avoid disturbs, some efforts have attempted to adjust the operating conditions of the nonvolatile memory device by reducing the pass voltage to a level less likely to cause read disturbs. However, decreasing the pass voltage requires a decrease in the program verify (PV) voltage threshold to retain a similar pass voltage window (the range of pass voltages that largely avoid read disturbs and program disturbs). Reducing the pass voltage hinders the retention window or endurance requirement of the nonvolatile memory device.

Accordingly, there is a need in the art to increase the performance of read operations and maximize the data retention properties of a non-volatile memory device.

### BRIEF SUMMARY OF EXEMPLARY EMBODIMENTS

In accordance with embodiments of the present invention, a nonvolatile memory device is provided that can improve data retention and avoid the occurrence of disturbs during read operations. As noted above, NAND flash memory devices can develop traps in the oxide layers surrounding a floating gate. After high temperature baking, electrons stored in the floating gate will escape to the substrate through these oxide traps and, as a result, eventually program operations will produce a lower threshold voltage for a “0” state memory cell. To counteract this effect, embodiments disclosed herein apply a coupling effect to a memory cell, which increases the threshold voltage of the floating gate of the memory cell. By counterbalancing the reduced voltage applied during program operations, this mechanism can improve the duration that the memory cell retains data and continue to provide accurate read performance.

In a first example embodiment, a method is provided for controlling a nonvolatile memory device that includes a matrix of memory cells, wherein each memory cell in the matrix includes a programmable floating gate. The nonvolatile memory device may be a flash memory, and in particular may be a NAND flash memory. The method includes programming, by a controller, a floating gate of a first memory cell of the nonvolatile memory device, and shifting, by the controller, a voltage of the floating gate of the first memory cell of the nonvolatile memory device by creating a coupling effect that impacts the floating gate of the first memory cell. For instance, creating the coupling effect may increase a threshold voltage of the floating gate of the first memory cell.

In some embodiments, creating the coupling effect may comprise causing, by the controller, a floating gate coupling effect between the first memory cell and one or more nearby memory cells by programming the one or more nearby memory cells. In this regard, each of the one or more nearby memory cells is a neighbor of the first memory cell. Additionally or alternatively, the one or more nearby memory cells may be dummy cells.

In a second example embodiment, an apparatus is provided for controlling a nonvolatile memory device that includes a matrix of memory cells, wherein each memory cell in the matrix includes a programmable floating gate. As above, the nonvolatile memory device may be a flash memory, and in particular may be a NAND flash memory The apparatus includes a control circuit configured to program floating gates of memory cells of the nonvolatile memory device, and shift a voltage of a floating gate of a first memory cell of the nonvolatile memory device by creating a coupling effect that impacts the floating gate of the first memory cell. For instance, creating the coupling effect may increase a threshold voltage of the floating gate of the first memory cell.

In some embodiments, creating the coupling effect may comprise causing a floating gate coupling effect between the first memory cell and one or more nearby memory cells by programming the one or more nearby memory cells. In this regard, each of the one or more nearby memory cells is a neighbor of the first memory cell. Additionally or alternatively, the one or more nearby memory cells may be dummy cells.

In yet another example embodiment, a nonvolatile memory device is provided. As above, the nonvolatile memory device may be a flash memory, and in particular may be a NAND flash memory. The nonvolatile memory device includes a matrix of memory cells, wherein each memory cell in the matrix includes a programmable floating gate. The nonvolatile memory device of this example embodiment also includes a control circuit for programming memory cells of the matrix. This control circuit is configured to shift a voltage of a floating gate of a first memory cell of the matrix of memory cells by creating a coupling effect that impacts the floating gate of the first memory cell. For instance, creating the coupling effect may increase a threshold voltage of the floating gate of the first memory cell.

In some embodiments, creating the coupling effect may comprise causing a floating gate coupling effect between the first memory cell and one or more nearby memory cells by programming the one or more nearby memory cells. In this regard, each of the one or more nearby memory cells is a neighbor of the first memory cell. Additionally or alternatively, the one or more nearby memory cells may be dummy cells.

The above summary is provided merely for purposes of summarizing some example embodiments to provide a basic understanding of some aspects of the invention. Accordingly, it will be appreciated that the above-described embodiments are merely examples and should not be construed to narrow the scope or spirit of the invention in any way. It will be appreciated that the scope of the invention encompasses many potential embodiments in addition to those here summarized, some of which will be further described below.

### BRIEF DESCRIPTION OF THE SEVERAL VIEWS OF THE DRAWINGS

Having thus described certain example embodiments of the present disclosure in general terms, reference will now be made to the accompanying drawings, which are not necessarily drawn to scale, and wherein:

FIG. 1 illustrates a block diagram of a semiconductor device including a control circuit and a series of nonvolatile memory elements, in accordance with example embodiments of the present invention.

FIG. 2A illustrates a top view of a matrix of memory cells included in a memory nonvolatile memory, in accordance with example embodiments of the present invention;

FIG. 2B illustrates a diagram of threshold voltage levels associated with a particular memory cell, in accordance with example embodiments of the present invention; and

FIG. 3A illustrates a top view of a modified matrix of memory cells included in a memory nonvolatile memory, in accordance with example embodiments of the present invention;

FIG. 3B illustrates a modified diagram of threshold voltage levels associated with a particular memory cell, in accordance with example embodiments of the present invention; and

FIG. 4 illustrates a flowchart of operations performed to improve data retention or read performance of a nonvolatile memory device, in accordance with example embodiments of the present invention.

### DETAILED DESCRIPTION

Some embodiments of the present invention will now be described more fully hereinafter with reference to the accompanying drawings, in which some, but not all embodiments of the inventions are shown. Indeed, these inventions may be embodied in many different forms and should not be construed as limited to the embodiments set forth herein; rather, these embodiments are provided so that this disclosure will satisfy applicable legal requirements. Like numbers refer to like elements throughout.

As used here, a “non-volatile memory device” refers to a semiconductor device which is able to store information even when the supply of electricity is removed. Non-volatile memory includes, without limitation, Mask Read-Only Memory, Programmable Read-Only Memory, Erasable Programmable Read-Only Memory, Electrically Erasable Programmable Read-Only Memory, and Flash Memory.

As used herein, a “substrate” may include any underlying material or materials upon which a device, a circuit, an epitaxial layer, or a semiconductor may be formed. Generally, a substrate may be used to define the layer or layers that underlie a semiconductor device or even forms the base layer of a semiconductor device. The substrate may include one or any combination of silicon, doped silicon, germanium, silicon germanium, semiconductor compounds, or other semiconductor materials.

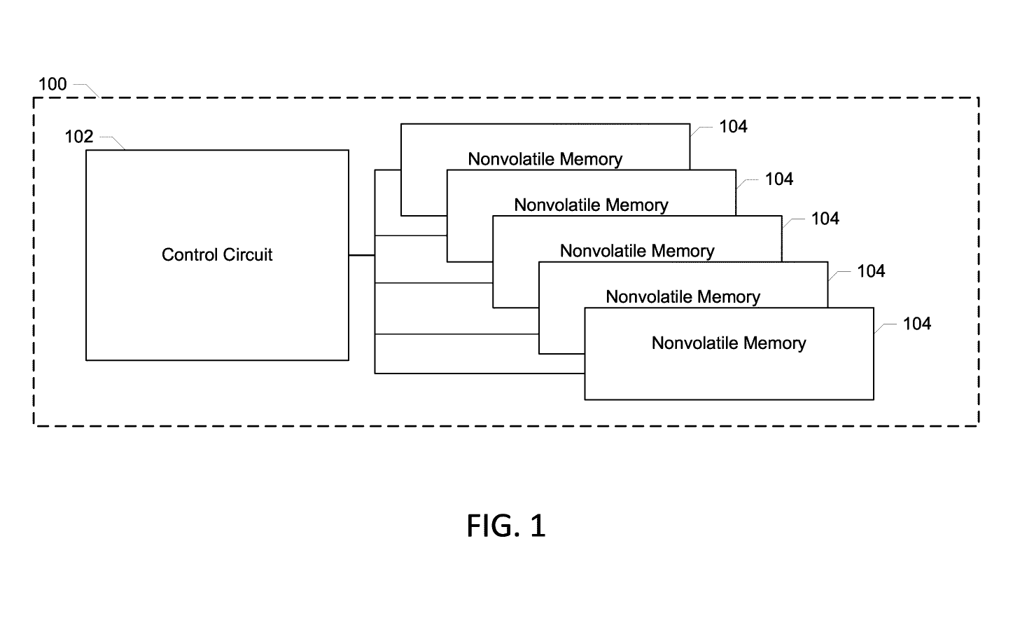

Turning now to FIG. 1, a block diagram of an example semiconductor device 100 is provided. This example semiconductor device includes both a control circuit 102 and a series of nonvolatile memories 104. The control circuit 102 communicates with each of the nonvolatile memories 104 and is configured to direct the read, program, erase, and other operations applied to the memory elements. In turn, each nonvolatile memory 104 may include a matrix of memory cells arranged in rows and columns. Each memory cell in the matrix includes a transistor structure having a gate, a drain, a source, and a channel defined between the drain and the source. Each memory cell is located at an intersection between a word line and a bit line, wherein the gate is connected to the word line, the drain is connected to the bit line, and the source is connected to a source line, which in turn is connected to common ground. The gate of a conventional flash memory cell generally comprises a dual-gate structure, including a control gate and a floating gate, wherein the floating gate is suspended between two oxide layers to trap electrons that program the cell.

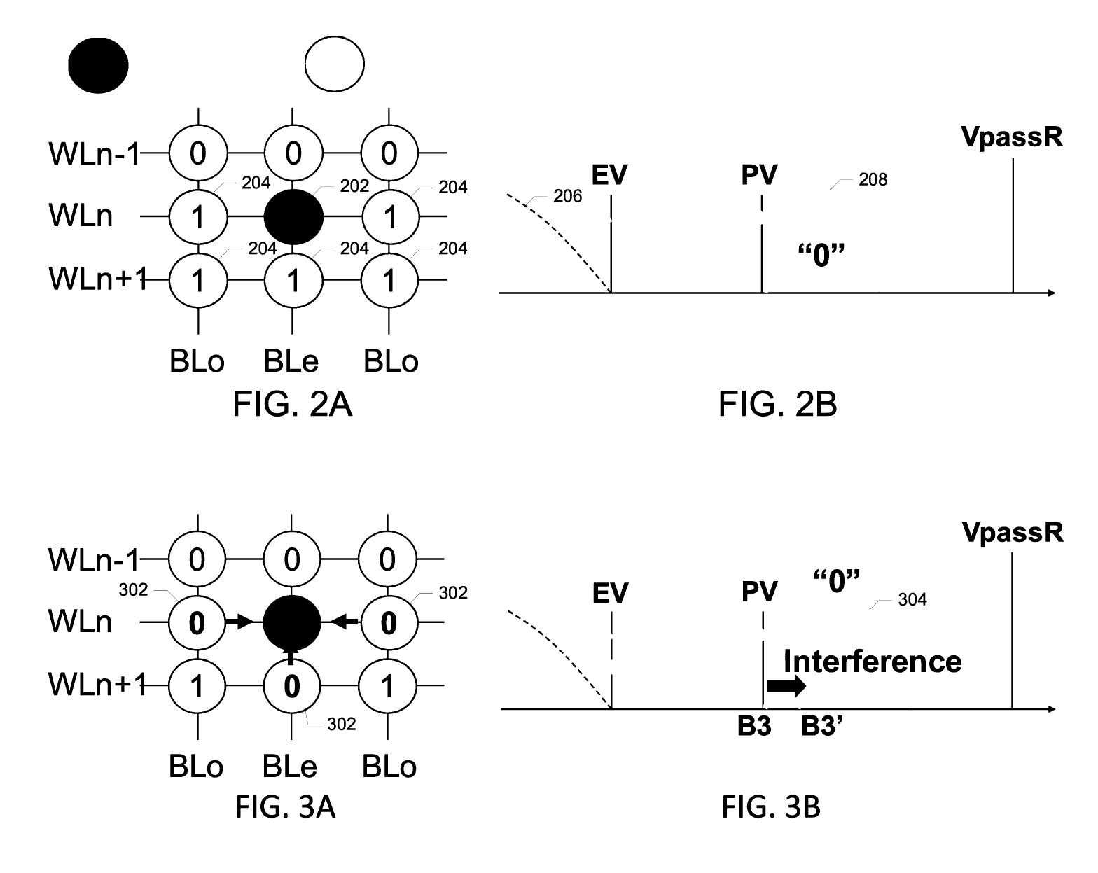

In FIG. 2A, an example matrix of memory cells is illustrated. Each memory cell in this example corresponds to a page. This matrix of memory cells is part of a block within a nonvolatile memory device (such as one of nonvolatile memories 104 described in connection with FIG. 1, above). Each block of the nonvolatile memory device includes a plurality of word lines (of which WLₙ₋₁, WLₙ, and WLₙ₊₁ are illustrated in FIG. 2A) that intersect a sequence of odd and even bit lines. In FIG. 2A, the illustrated portion of the block illustrates two odd bit lines (BLₒ) surrounding an even bit line (BLₑ). A memory cell is located at each intersecting point of a word line and a bit line. Because there are three word lines and three bit lines shown, FIG. 2A illustrates 9 total memory cells.

As the legend above the diagram illustrates, memory cell 202 comprises a data page, and memory cells 204 illustrate dummy pages (or dummy cells). In this regard, the data patterns of dummy pages 204 are unrestrained and thus can have any data pattern, and as will be described below, these dummy pages 204 are not intended to store data, but are used to manipulate the properties of data page 202. Thus, because they need not be data storing memory cells in embodiments described herein, dummy pages 204 can be freely assigned at any time without impacting the data storage capability of the nonvolatile memory device. Similarly, because dummy pages 204 are not needed for storing data, there are thus no restrictions on the data patterns available for programming dummy pages 204, and they can be assigned to a “1”state or a “0” state as necessary for optimizing the data retention and/or read properties of data page 202.

Data page 202, is located within a series of neighbor memory cells. In this regard, the term “neighbor memory cells” herein can refer to all direct neighbors of a memory cell (e.g., for data page 202, this may represent the eight neighboring memory cells surrounding data page 202 in FIG. 2A), non-diagonally related neighbors (e.g., the memory cells to the left, right, above, and below data page 202 as shown in FIG. 2A), the face-to-face neighbors (e.g., the memory cells directly above and below data page 202 in FIG. 2A), as is typical with interior memory cells in a traditional matrix arrangement. It should be understood that while there are eight directly neighboring memory cells for each interior memory cell of a traditional nonvolatile memory, depending on the scale and chip density of the nonvolatile memory device, there may also be more nearby memory cells that can be utilized as dummy cells. In this regard, while directly neighboring cells typically demonstrate cross-coupling effects on a target memory cell, other memory cells may also demonstrate such coupling effects. Thus, two memory cells may be considered “nearby” if there exists a cross-coupling effect between them.

Turning now to FIG. 2B, a diagram is provided that illustrates threshold voltage levels associated with data page 202 from FIG. 2A. In response to a program operation in which data page 202 is updated from a “1” unprogrammed (or erased) state to a “0” programmed state, the diagram shown in FIG. 2B illustrates that data page 202 has an associated voltage threshold that has moved from a first voltage range 204 associated with the “1” state to a voltage range 206 associated with the “0” state. Similarly, an erase verify threshold EV demarcates the upper voltage boundary of the “1” state and a program verify threshold PV demarcates the lower voltage boundary of the “0” state (the margin between the EV threshold and the PV threshold comprises a voltage range within which a read voltage can be applied to detect the state of a target memory cell). FIG. 2B further illustrates that the pass voltage (VpassR) is higher than all of the erase verify threshold EV, the “1” state voltage range 204, the program verify threshold PV, and the programmed state voltage range 206, which ensures that any page to which the pass voltage is applied will be conductive, regardless of its programmed state.

Turning now to FIG. 3A, a modification to the matrix of FIG. 2A is illustrated. The memory cells shown in FIG. 3A correspond to the memory cells illustrated in FIG. 2A, except that three of the dummy pages 204 (identified in FIG. 3A as memory cells 302) have undergone program operations to transition from a “1” state to the higher-voltage “0” state. The arrows from each of these memory cells 302 toward data page 202 indicate that this change produces a cross-coupling effect in data page 202.

The cross-coupling effect is demonstrated in FIG. 3B, which illustrates a modified diagram of threshold voltage levels associated with data page 202. In particular, as illustrated by the dotted line indicating the change of dummy pages 302 from a “1” state to a “0” state, and the dotted voltage range now contained in those memory cells, a floating gate cross-coupling effect is applied to the voltage of the floating gate of data page 202. The interference produced by stray fields from the neighboring memory cells 302 causes an increase in the voltage of data page 202.

As described above, NAND flash memory devices can develop traps in the oxide layers surrounding a floating gate, and when electrons fill these traps, the potential barrier of the oxide layers increase and eventually program operations begin to produce a lower threshold voltage for a “0” state memory cell. When that threshold voltage sinks into the margin between the EV and PV voltage thresholds, there is a possibility of data retention problems, because a read operation might misidentify the state of the memory cell. By selecting an appropriate number of neighboring dummy cells and programming those cells after programming the original memory cell, the voltage threshold of the original memory cell is boosted, thus diminishing the likelihood of a data retention problem. To counteract this effect, embodiments disclosed herein apply a coupling effect to a memory cell, which increases the threshold voltage of the floating gate of the memory cell. By counterbalancing the reduced voltage applied during program operations, this mechanism can improve the duration that the memory cell retains data and continue to provide accurate read performance.

Although five of the illustrated neighboring cells in FIGS. 2A and 3A are designated as dummy pages 204, more or fewer neighboring memory cells may be designated as dummy pages, depending on the tradeoffs between read performance, data retention, chip density, and program performance desired for a given implementation. Similarly, the wear applied to the nonvolatile memory device may also play a role in determining the appropriate number of neighboring dummy cells that are necessary to ensure data retention and read performance.

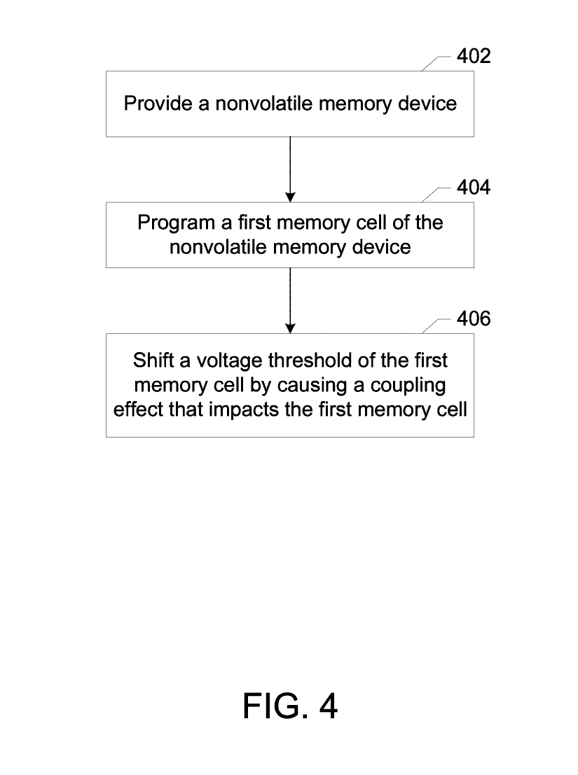

Turning now to FIG. 4, a flowchart is illustrated that describes operations performed to improve data retention or read performance of a nonvolatile memory device, in accordance with example embodiments of the present invention. In operation 402, a nonvolatile memory device is provided. This nonvolatile memory device may include an on-chip control circuit, as illustrated in FIG. 1. In operation 404, a controller (which may be the on-chip control circuit or another mechanism for programming the nonvolatile memory device as would be understood by one having ordinary skill in the art) programs a first memory cell of the nonvolatile memory device. It should be understood that any number of program operations or other operations may be performed on the nonvolatile memory device, so long as at least one memory cell (e.g., the first memory cell referenced above) has been initially programmed in advance of operation 406. Turning then to operation 406, the controller shifts a voltage threshold of the first memory cell by causing a coupling effect that impacts the first memory cell. This voltage shift may be created by the controller programming one or more nearby memory cells, which causes a floating gate coupling effect between the first memory cell and one or more nearby memory cells. These nearby cells may comprise neighboring memory cells, and furthermore may comprise dummy cells, both of which are described in greater detail above. In any event, the coupling effect may thus increase the threshold voltage of the first memory cell.

Accordingly, as described herein, a nonvolatile memory device, a controller configured to program a nonvolatile memory device, and a method of controlling a nonvolatile memory device are provided. Embodiments of the present invention thus enable improved data retention and enhanced read performance of the underlying nonvolatile memory device by boosting a threshold voltage of memory cells having a “0” state, thus mitigating the possibility that read operations will misidentify those memory cells. In particular, by inducing a coupling effect on a target memory cell, these data retention properties and read performance can be enhanced. In some embodiments, the coupling effect comprises a floating gate coupling effect and is induced by memory cells nearby the target memory cell. In other embodiments, other coupling effects may be considered without departing from the spirit or scope of the present invention.

It should be understood that while the present invention is described for clarity using a target memory cell that is surrounded by eight other memory cells in the nonvolatile memory device, the nonvolatile memory device may contain any number of memory cells and in embodiments inducing a floating gate coupling effect, any number of nearby memory cells may be used to induce this effect. Furthermore, although some embodiments of the present invention comprise or utilize a NAND flash memory device, embodiments of the present invention may comprise or utilize other nonvolatile semiconductor devices, such as NOR flash memory or the like.

Many modifications and other embodiments of the inventions set forth herein will come to mind to one skilled in the art to which these inventions pertain having the benefit of the teachings presented in the foregoing descriptions and the associated drawings. Therefore, it is to be understood that the inventions are not to be limited to the specific embodiments disclosed and that modifications and other embodiments are intended to be included within the scope of the appended claims. Moreover, although the foregoing descriptions and the associated drawings describe example embodiments in the context of certain example combinations of elements and/or functions, it should be appreciated that different combinations of elements and/or functions may be provided by alternative embodiments without departing from the scope of the appended claims. In this regard, for example, different combinations of elements and/or functions than those explicitly described above are also contemplated as may be set forth in some of the appended claims. Although specific terms are employed herein, they are used in a generic and descriptive sense only and not for purposes of limitation.

1. A method for controlling a nonvolatile memory device that includes a matrix of memory cells, wherein each memory cell in the matrix includes a programmable floating gate, the method comprising:
programming, by a controller, a floating gate of a first memory cell of the nonvolatile memory device to a first voltage at least equal to or higher than a program verify threshold voltage; and
shifting, by the controller, the first voltage to a second voltage higher than the program verify threshold voltage by creating a coupling effect that impacts the floating gate of the first memory cell.

2. The method of claim 1, wherein creating the coupling effect increases a threshold voltage of the floating gate of the first memory cell.

3. The method of claim 1, wherein creating the coupling effect comprises:
causing, by the controller, a floating gate coupling effect between the first memory cell and one or more nearby memory cells by programming the one or more nearby memory cells.

4. The method of claim 3, wherein each of the one or more nearby memory cells is a neighbor of the first memory cell.

5. The method of claim 3, wherein the one or more nearby memory cells comprise dummy cells.

6. The method of claim 1, wherein the nonvolatile memory device comprises a flash memory.

7. The method of claim 6, wherein the nonvolatile memory device comprises a NAND flash memory.

8. An apparatus for controlling a nonvolatile memory device that includes a matrix of memory cells, wherein each memory cell in the matrix includes a programmable floating gate, the apparatus comprising a control circuit configured to:
program floating gate of a first memory cell of the nonvolatile memory device to a first voltage at least equal to or higher than a program verify threshold voltage; and
shift the first voltage to a second voltage higher than the program verify threshold voltage by creating a coupling effect that impacts the floating gate of the first memory cell.

9. The apparatus of claim 8, wherein creating the coupling effect increases a threshold voltage of the floating gate of the first memory cell.

10. The apparatus of claim 8, wherein creating the coupling effect comprises:
causing a floating gate coupling effect between the first memory cell and one or more nearby memory cells by programming the one or more nearby memory cells.

11. The apparatus of claim 10, wherein each of the one or more nearby memory cells is a neighbor of the first memory cell.

12. The apparatus of claim 10, wherein the one or more nearby memory cells comprise dummy cells.

13. The apparatus of claim 8, wherein the nonvolatile memory device comprises a flash memory.

14. The apparatus of claim 13, wherein the nonvolatile memory device comprises a NAND flash memory.

15. A nonvolatile memory device comprising:
a matrix of memory cells, wherein each memory cell in the matrix includes a programmable floating gate; and
a control circuit for programming memory cells of the matrix, wherein the control circuit is configured to
program a floating gate of a first memory cell of the matrix to a first voltage at least equal to or higher than a program verify threshold voltage; and
shift the first voltage to a second voltage higher than the program verify threshold voltage by creating a coupling effect that impacts the floating gate of the first memory cell.

16. The nonvolatile memory device of claim 15, wherein creating the coupling effect increases a threshold voltage of the floating gate of the first memory cell.

17. The nonvolatile memory device of claim 15, wherein creating the coupling effect comprises:
causing a floating gate coupling effect between the first memory cell and one or more nearby memory cells by programming the one or more nearby memory cells.

18. The nonvolatile memory device of claim 17, wherein each of the one or more nearby memory cells is a neighbor of the first memory cell.

19. The nonvolatile memory device of claim 17, wherein the one or more nearby memory cells comprise dummy cells.

20. The nonvolatile memory device of claim 15, wherein the nonvolatile memory device comprises a flash memory.
